(19) United States
(12) Patent Application Publication
(10) Pub. No.: US 2014/0290739 A1
(43) Pub. Date: Oct. 2, 2014

(54) THIN-FILM SOLAR BATTERY AND METHOD OF MAKING SAME

(71) Applicant: Hiroshi Deguchi, Kanagawa (JP)

(72) Inventor: Hiroshi Deguchi, Kanagawa (JP)

(73) Assignee: RICOH COMPANY, LTD., Tokyo (JP)

(21) Appl. No.: 14/221,569

(22) Filed: Mar. 21, 2014

(30) Foreign Application Priority Data
Mar. 27, 2013 (JP) 2013-067393

(51) Int. Cl. H01L 31/032; H01L 31/18

(52) U.S. Cl. CPC H01L 31/0322; H01L 31/18
USPC 136/258; 136/262; 136/260; 204/192.25

(57) ABSTRACT

A thin-film solar battery includes a substrate, a first electrode, a photoelectric conversion layer, and a second electrode. The first electrode, the photoelectric conversion layer, and the second electrode are laminated on the substrate. The photoelectric conversion layer has a laminated layer structure which includes at least a p-type layer and an n-type layer. The p-type layer is formed of Cu, In, Ga, and Se, and a composition ratio of Se of the p-type layer is equal to or higher than 40 atomic % and less than 50 atomic %. The n-type layer is a compound of an element of at least one Group selected from Group 2, Group 7, and Group 12, an element of Group 13, and an element of Group 16, and contains at least In as the element of Group 13 and at least S as the element of Group 16.

### CROSS-REFERENCE TO RELATED APPLICATIONS

This patent application is based on and claims priority pursuant to 35 U.S.C. §119 to Japanese Patent Application No. 2013-067393, filed on Mar. 27, 2013, in the Japan Patent Office, the entire disclosure of which is hereby incorporated by reference herein.

### BACKGROUND

1. Technical Field

Embodiments of the present invention relates to a thin-film solar battery and a method of making the thin-film solar battery.

2. Description of the Related Art

In recent years, the importance of reduction of CO₂ for global warming prevention and clean energy that will replace fossil energy and nuclear energy is growing. Among clean energy resources, a solar battery has advantages in that (1) the source of energy thereof is so enormous that it will not be depleted, (2) it is a clean energy source and does not emit CO₂ during power generation, (3) it enables self-provision of electric power, and the like, and thus has been developed further. Among various kinds of solar batteries, a thin-film solar battery can have a thin film thickness of a photoelectric conversion layer, which is advantageous in terms of costs, and thus research and development thereof have been actively conducted. Among these, a battery using a compound-based semiconductor film as a photoelectric conversion layer (light-absorbing layer) of an inorganic compound-based thin-film solar battery is known. As the compound-based semiconductor film, a material of a chalcopyrite compound (CuInSe₂, CuInS₂, CuInGaSe₂, or the like) which is called as a CIS-based or CIGS-based material or the like is known. The material can be used as a p-type photoelectric conversion layer in which positive holes (holes) generated by absorbing light move. As a configuration of a thin-film solar battery that uses such a p-type photoelectric conversion layer, a laminated layer structure which includes a lower electrode, a p-type photoelectric conversion layer, a buffer layer, a window layer (which is an n-type semiconductor film in any case), and an upper electrode (transparent electrode) is widely known.

In a thin-film solar battery with the laminated layer structure, photoelectric conversion is performed by causing positive holes which are generated in a p-type photoelectric conversion layer by absorbing light incident through a window layer (n-type semiconductor film) to move as carriers. In addition, a buffer layer which is a very thin compound semiconductor film is provided between the p-type photoelectric conversion layer and the window layer (n-type semiconductor film). The buffer layer has a function of increasing overall energy efficiency of a solar battery by reducing defects of the interface between the p-type photoelectric conversion layer and the window layer (n-type semiconductor film) to suppress recombination of carriers, and thus photoelectric conversion does not occur. As methods of making the compound-based semiconductor film constituting the thin-film solar battery, a method of using vacuum vapor deposition and a method of performing thermal treatment in an atmosphere containing selenium (a selenization method or a precursor method) have been widely used for the p-type photoelectric conversion layer; and a solution growth method (CBD method: Chemical Bath Deposition method) in which a film is formed through a chemical reaction using a solution has been widely used for the buffer layer. In such a thin-film solar battery, improvement in energy efficiency of the photoelectric conversion layer itself is very important. Generally, it is known that a material of the p-type photoelectric conversion layer is in a favorable crystalline state and has a satisfactory photoelectric conversion characteristic after being treated at a high temperature.

JP-2003-008039-A discloses a thin-film solar battery with the laminated layer structure in which a CIS-based compound film is used as a p-type photoelectric conversion layer, a ZnIn-based compound semiconductor film containing Zn—In—Se or S (ZnIn₂Se₄ or the like) is used as a buffer layer, and ZnO is used as a window layer (n-type semiconductor film). In the course of making the thin-film solar battery, if constituent components are mutually diffused between the CIS-based compound film serving as a p-type photoelectric conversion layer and the buffer layer, energy efficiency as the solar battery deteriorates, and thus suppression of the mutual diffusion of the p-type photoelectric conversion layer and the buffer layer is required. Thus, in the thin-film solar battery, the ZnIn-based compound semiconductor film that does not cause mutual diffusion with the CIS-based compound film is used as a buffer layer. In addition, by using the selenization method of performing thermal treatment at a high temperature of 400° C. to 500° C. in an atmosphere containing selenium as a method of making the CIS-based compound film and the ZnIn-based compound semiconductor film, the crystalline state is made to be favorable, the photoelectric conversion characteristic of the p-type photoelectric conversion layer is made to be satisfactory, and thereby energy efficiency is improved. In addition, WO2005064692-A1 discloses that a ZnIn-based compound semiconductor film containing ZnIn (O, OH, or S) or the like used as a buffer layer is made by the CBD method for a thin-film solar battery with the laminated layer structure.

It is important for a thin-film solar battery to acquire high energy efficiency and to lower manufacturing costs. In order to lower manufacturing costs, it is required to realize high production efficiency using a simple manufacturing method. However, for the thin-film solar battery of JP-2003-008039-A, the selenization method with high-temperature treatment (400° C. to 500° C.) is used in film formation of the p-type photoelectric conversion layer and the buffer layer for the purpose of improving energy efficiency. The selenization method in which such high-temperature treatment is performed requires time for temperature rising or falling and thus has difficulty in realizing high production efficiency. In addition, in the thin-film solar battery of WO2005064692-A1, the CBD method is used in providing the buffer layer, but when it is considered that the CBD method is a chemical reaction using a solution and pre- and post-preparation processes are vacuum deposition, the method is not appropriate for realizing high production efficiency, and thus it is not desirable in terms of an operation rate and manufacture management. Furthermore, recently, CdTe that is a p-type photoelectric conversion layer can be made by one kind of vacuum film deposition that is called a close-spaced sublimation method with higher production efficiency than the existing vacuum vapor deposition method or selenization method, and has been put into practical use. However, since a thermal treatment temperature in the close-spaced sublimation method is as high as about 600° C., further improvement in production efficiency is difficult to attain.

### SUMMARY

In at least one embodiment of this disclosure, there is provided a thin-film solar battery including a substrate, a first electrode, a photoelectric conversion layer, and a second electrode. The first electrode, the photoelectric conversion layer, and the second electrode are laminated on the substrate. The photoelectric conversion layer has a laminated layer structure which includes at least a p-type layer and an n-type layer. The p-type layer is formed of Cu, In, Ga, and Se, and a composition ratio of Se of the p-type layer is equal to or higher than 40 atomic % and less than 50 atomic %. The n-type layer is a compound of an element of at least one Group selected from Group 2, Group 7, and Group 12, an element of Group 13, and an element of Group 16, and contains at least In as the element of Group 13 and at least S as the element of Group 16.

In at least one embodiment of this disclosure, there is provided a method of making the above-described thin-film solar battery. The method includes forming the photoelectric conversion layer using a sputtering method, and forming the p-type layer without using a process of selenization or of supplementing elemental selenium using Se or H₂Se.

### BRIEF DESCRIPTION OF THE SEVERAL VIEWS OF THE DRAWINGS

The aforementioned and other aspects, features, and advantages of the present disclosure would be better understood by reference to the following detailed description when considered in connection with the accompanying drawings, wherein:

FIG. 1 is a cross-sectional view showing a configuration of a thin-film solar battery of the present invention;

FIG. 2 is a top view of the thin-film solar battery of the present invention;

FIG. 3 is a graph showing current density-voltage characteristics of thin-film solar batteries of Example 1 and Comparative Example 1;

FIG. 4 is a graph showing current density-voltage characteristics of thin-film solar batteries of Example 2 and Comparative Example 2;

FIG. 5 is a graph showing a current density-voltage characteristic solar battery of Example 6;

FIG. 6 is a graph showing a current density-voltage characteristic of a thin-film solar battery of Example 7;

FIG. 7 is a graph showing a current density-voltage characteristic of a thin-film solar battery of Example 8;

FIG. 8 is a graph showing a current density-voltage characteristic of a thin-film solar battery of Example 9;

FIG. 9 is a graph showing a current density-voltage characteristic of a thin-film solar battery of Example 10;

FIG. 10 is a graph showing a current density-voltage characteristic of a thin-film solar battery of Example 11;

FIG. 11 is a graph showing a current density-voltage characteristic of a thin-film solar battery of Example 12;

FIG. 12 is a graph showing a current density-voltage characteristic of a thin-film solar battery of Example 13;

FIG. 13 is a graph showing a current density-voltage characteristic of a thin-film solar battery of Example 14;

FIG. 14 is a graph showing a current density-voltage characteristic of a thin-film solar battery of Example 15;

FIG. 15 is a graph showing a current density-voltage characteristic of a thin-film solar battery of Example 16;

FIG. 16 is a graph showing a current density-voltage characteristic of a thin-film solar battery of Example 17; and

FIG. 17 is a graph showing a current density-voltage characteristic of a thin-film solar battery of Comparative Example 14;

FIG. 18 is a graph showing a dependence of conversion efficiency of a thin-film solar battery of Example 18 on film thickness of a CuInGaSe layer; and

FIG. 19 is a graph showing a dependence of conversion efficiency of a thin-film solar battery of Example 19 on film thickness of a CuInGaSe layer.

The accompanying drawings are intended to depict exemplary embodiments of the present disclosure and should not be interpreted to limit the scope thereof. The accompanying drawings are not to be considered as drawn to scale unless explicitly noted.

### DETAILED DESCRIPTION OF EMBODIMENTS

In describing embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner and achieve similar results.

Although the exemplary embodiments are described with technical limitations with reference to the attached drawings, such description is not intended to limit the scope of the invention and all of the components or elements described in the exemplary embodiments of this invention are not necessarily indispensable to the present invention.

Referring now to the drawings, exemplary embodiments of the present invention are described below. In the drawings for explaining the following exemplary embodiments, the same reference codes are allocated to elements (members or components) having the same function or shape and redundant descriptions thereof are omitted below.

Below, an embodiment 1) of the present invention is described in detail.

1) a thin-film solar battery including a substrate, a first electrode, a photoelectric conversion layer, and a second electrode. The first electrode, the photoelectric conversion layer, and the second electrode are laminated on the substrate. The photoelectric conversion layer has a laminated layer structure which includes at least a p-type layer and an n-type layer. The p-type layer is formed of Cu, In, Ga, and Se, and a composition ratio of Se of the p-type layer is equal to or higher than 40 atomic % and less than 50 atomic %. The n-type layer is a compound of an element of at least one Group selected from Group 2, Group 7, and Group 12, an element of Group 13, and an element of Group 16, and contains at least In as the element of Group 13 and at least S as the element of Group 16.

However, since embodiments of the present invention also include the following 2) to 7), the following 2) to 7) are also described below.

2) The thin-film solar battery described in 1), wherein element of at least one Group selected from Group 2, Group 7, and Group 12 in the n-type layer is at least one selected from Mg, Ca, Sr, Ba, Zn, Cd, and Mn.

3) The thin-film solar battery described in 1) or 2), wherein the n-type layer contains at least one of Ga, Al, and B as the element of Group 13 in addition to In, and contains at least one of Te, Se, and O as the element of Group 16 in addition to S.

4) The thin-film solar battery described in any one of 1) to 3), wherein the n-type layer contains Zn, In, and S or Zn, Sr, In, and S.

5) The thin-film solar battery described in any one of 1) to 4), wherein a structural state of the n-type layer is an amorphous state.

6) The thin-film solar battery described in any one of 1) to 5), wherein the photoelectric conversion layer is formed using a sputtering method, and the p-type layer is formed without using a process of selenization or of supplementing elemental selenium using Se or H₂Se.

7) A method of making the thin-film solar battery described in any one of 1) to 5), the method comprising forming the photoelectric conversion layer using a sputtering method; and forming the p-type layer without using a process of selenization or of supplementing elemental selenium using Se or H₂Se.

The present inventors developed a thin-film solar battery that enables energy efficiency and satisfactorily high production efficiency to be compatible using an n-type layer material which is also employed in the present invention and filed an application thereof (refer to JP 2011-216874A, which will hereinafter be referred to as the previous application). Particularly, the point that film formation processes of all layers are performed using sputtering method is very important for obtaining a high level of production efficiency that cannot be achieved by the related art, because film formation using the sputtering method brings a higher operation rate than other film formation methods and thus easily facilitates raising a film formation rate. In addition, as a result of research conducted thereafter, it has been found that a thin-film solar battery that has even higher energy efficiency can be obtained by using Cu, In, Ga, and Se that are formed as a film using, for a p-type layer, the sputtering method that is the same film formation method as for an n-type layer material. So-called CIGS that includes Cu, In, Ga, and Se is the most famous material for a p-type photoelectric conversion layer or a p-type light-absorbing layer of a compound thin-film solar battery, and has already been commercialized. In the past, formation of a film of CIGS was performed using a multiple vapor deposition method or the precursor method, but recently, an example of using the sputtering method has been reported (Prog. Photovolt: Res. Appl. 2011; 160-164). However, in the film formation methods, selenization or a process of supplementing elemental selenium (hereinafter referred to as a selenization process) using Se or H₂Se is inevitably adopted, and without using the process, satisfactory conversion efficiency cannot be obtained. Se or H₂Se is fairly toxic, so that special equipment is required for treating the material, which is one cause of a cost increase.

In this disclosure, without using the selenization process that was essential in the past, a way of improving energy efficiency is found by combining a CIGS film formed using the sputtering method even at a relatively low temperature and an n-type layer relating to the invention of the previous application. Since it is possible to use the same film formation process for the CIGS film and the n-type layer in the combination, satisfactorily high production efficiency can be realized. In a film formation method of a CIGS film of the past, it is known that an amount of selenium in which the composition ratio of selenium that is the stoichiometric composition of the CIGS film is about 50 atomic % or higher can be realized and that this leads to high efficiency. In contrast to this, in the present invention that does not use the selenization process, it was found that a thin-film solar battery having even higher energy efficiency than the p-type material implemented in the previous application is obtained in the range of the composition ratio of selenium of less than 50 atomic %, to be specific, equal to or higher than 40 atomic % and less than 50 atomic %, and preferably equal to or higher than 45 atomic % and less than 50 atomic %.

A thickness of a p-type layer is preferably 10 nm to 1 μm, and more preferably 200 nm to 500 nm. In examination results of this disclosure, when the thickness exceeds 1 μm, conversion efficiency deteriorates. A CIGS layer used as a p-type photoelectric layer or a p-type light-absorbing layer of a comparative compound thin-film solar battery has a film thickness of generally 1 μm or greater or, at minimum, 600 nm or greater. This is because the CIGS layer efficiently absorbs sunlight. If the film thickness is smaller, the amount of sunlight absorbed with the CIGS layer is lower. As a result, the amount of generated carriers (that are positive holes because the CIGS layer is a p-type layer) would decrease, thus deteriorating conversion efficiency.

In a configuration of one or more embodiments of this disclosure, the CIGS layer is more important in operation as a transport layer to efficiently transport carriers generated by irradiation of sunlight than operation as a power generating layer. As the film thickness is smaller, the transport performance of carriers is higher. Accordingly, the optimal film thickness of the CIGS layer according to embodiments of this disclosure is preferably smaller than an optical film thickness of a typical CIGS layer. However, if the film thickness is too small, the film quality of the CIGS layer would deteriorate. As a result, the transport efficiency of carriers would deteriorate, thus reducing conversion efficiency. The thickness of the p-type layer can he measured using, for example, an optical method (ellipsometry, a spectroscopic film thickness meter using interference of light, or the like) or a mechanical method (for example, a palpation meter or an atomic force microscope (AFM)).

For an n-type layer, a material that is a compound of element of at least one Group selected from Group 2, Group 7, and Group 12, an element of Group 13, and an element of Group 16, and contains at least In as the element of Group 13 and contains at least S as the element of Group 16 (hereinafter referred to as a II-III(In)-VI(S) compound) is used. Here, ‘II’ represents at least one Group selected from Group 2, Group 7, and Group 12. ‘III(In)’ represents Group 13 indicating that at least In is contained. ‘VI(S)’ represents Group 16 indicating that at least S is contained. As II, at least one element selected from Mg, Ca, Sr, and Ba of Group 2, Zn and Cd of Group 12, and Mn of Group 7 is preferable. In addition, a II-III(In)-VI(S) compound thin film that is made at a low temperature (equal to or lower than 300° C.) shows an equivalent or more satisfactory photoelectric conversion characteristic and degree of carrier mobility as compared with a compound thin film that is made at a high temperature (400° C. to 500° C.). In other words, even when a II-III(In)-VI(S) compound thin film is made at a low temperature, it can be used as an n-type photoelectric conversion layer showing satisfactory energy efficiency. As a film formation method of the n-type layer, the vacuum vapor deposition method, the sputtering method, the precursor method, a coating method in which a material is made into ink and coated so as to form a film, or the like can be used.

In the thin-film solar battery according to an embodiment of the present invention, a photoelectric conversion layer is configured such that the p-type layer and the n-type layer formed of the II-III(In)-VI(S) compound thin film are laminated, and thus energy efficiency of the photoelectric conversion layer itself can be improved as compared with a configuration of the past in which a photoelectric conversion layer is constituted only with a p-type layer. In order to improve energy efficiency of the photoelectric conversion layer itself, measures were taken to enable the photoelectric conversion layer of the past constituted only with the p-type layer to be in a favorable crystalline state by making the p-type layer at a high temperature (400° C. to 500° C.). In contrast to this, in the embodiment of the present invention, by employing the photoelectric conversion layer constituted with the laminated p-type layer and n-type layer, energy efficiency of the photoelectric conversion layer itself can be improved without depending on high-temperature manufacture.

In addition, in the thin-film solar buttery of the past that uses the photoelectric conversion layer constituted only with the p-type layer, a buffer layer that does not cause photoelectric conversion is provided between a transparent conductive layer (n-type semiconductor film) and the p-type photoelectric conversion layer, and thus defects of the interface are reduced to suppress recombination of carriers, and accordingly, overall energy efficiency of the solar battery is improved. In contrast to this, the thin-film solar battery of the present invention has a laminated layer structure which includes a first electrode, the photoelectric conversion layer in which the p-type layer and the n-type layer are laminated, and a second electrode, and is not provided with a buffer layer. For this reason, a manufacturing process called the CBD method of the past which was used in formation of a buffer layer hindering realization of high production efficiency is no longer necessary. In short, in the thin-film solar battery of the present invention, the photoelectric conversion layer, which is obtained by laminating the p-type layer and the n-type layer, has high energy efficiency, and can be produced at a low temperature, is provided between the second electrode and the first electrode, and thus satisfactorily higher production efficiency than in the past can be realized.

Here, a thin-film solar battery according to an embodiment of the present invention is described with reference to drawings.

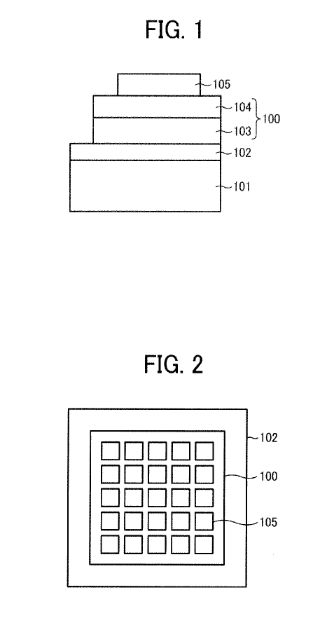

FIG. 1 is a cross-sectional view showing a layer structure of a thin-film solar battery according to an embodiment of the present invention. As shown in FIG. 1, the battery has the layer structure in which a first electrode 102, a photoelectric conversion layer 100 in which a p-type layer 103 and an n-type layer 104 are laminated, and a second electrode 105 are laminated on a supporting substrate 101.

—Supporting Substrate—

There is no particular limitation on the supporting substrate 101, a substrate can be appropriately selected according to a purpose, and examples thereof include a glass substrate, a quartz substrate, a plastic substrate, and the like. A surface of the supporting substrate 101 on which films are prepared may have an uneven structure. Due to a light confinement effect caused by light scattering, a light-absorbing ratio increases. Examples of a material of the plastic substrate include polycarbonate and the like. A thickness of the supporting substrate is preferably 50 μm to 10 mm.

—First Electrode—

For the first electrode 102, a metal material, for example, aluminum, silver, gold, platinum, or molybdenum can be used. In order to be in ohmic contact, it is necessary to select a material optimum for the material of the photoelectric conversion layer 100. In addition, it is required to have good adhesion to the supporting substrate 101. As a method of forming the first electrode 102, for example, the vacuum vapor deposition method, the sputtering method, or the like can be used. A thickness of the first electrode 102 is preferably equal to or thicker than 200 nm, and is decided under conditions including a sufficiently low resistivity and a high degree of adhesion.

—Photoelectric Conversion Layer—

The photoelectric conversion layer 100 has the laminated layer structure which includes the p-type layer 103 and the n-type layer 104. The materials of the p-type layer 103 and n-type layer 104 are as described above. In addition, a band-gap (Eg) of the photoelectric conversion layer 100 is preferably about 1 eV to 3 eV, and more preferably around 2 eV. When application to a multi-junction type top cell (on a light incident side) is considered, wider Eg is preferable, rather than setting the band-gap to a normal Eg of 1 eV to 1.4 eV as a single junction thin-film solar battery of the past. On the other hand, it is better for the multi-junction bottom cell side to have Eg narrower than 1 eV. Among the elements of II of the n-type layer, Zn is particularly preferable in terms of structure stability and environment compatibility. Furthermore, a mixture of two elements of Zn and Sr is preferable. Examples of materials that allow Eg to fall within the range of 2 eV to 2.5 eV include ZnIn₂S₄, CdIn₂S₄, and the like.

Furthermore, in a method of adjusting Eg, any one of In, Ga, Al, and B which are the Group 13 elements or a mixture of a plurality of the elements, any one of S, Se, and O which are the Group 16 elements or a mixture of a plurality of the elements can be used. However, when any of Ga, Al, and B of Group 13 or a mixture thereof, or O or the like of Group 16 is used, Eg excessively increases, and thus it is necessary to contain at least In as a constituent element of Group 13 and S as a constituent element of Group 16. With regard to Eg of the n-type layer, it is useful not only for selection of wavelength of incident light as described above, but also for optimization of an open voltage Voc that is obtained from a difference between Eg of the n-type layer and Eg of the p-type layer.

On the other hand, in the thin-film solar battery disclosed in JP 2003-8039A, a buffer layer formed of an extremely thin ZnInS thin film having a thickness less than 100 nm is provided between a photoelectric conversion layer and a translucent material layer. For the buffer layer, a highly resistive n-type semiconductor is used in order to reduce defects of the interface between the photoelectric conversion layer and the translucent material layer and to prevent recombination of carriers. The buffer layer itself contributes little to power generation, but fulfills the aforementioned functions even when the film thickness thereof is thin. In contrast to this, since the II-III(In)-VI(S) compound thin film in this embodiment of the present invention is used as the n-type layer 104 of the photoelectric conversion layer 100, a film thickness thereof can be set to 200 nm to 2 μm, and preferably 200 nm to 1 μm so as to be thick for the purpose of absorbing a sufficient amount of light. As described above, the II-III(In)-VI(S) compound thin film in this embodiment of the present invention is formed of the elements similarly used in the butler layer of the past, but the functions thereof are different.

A composition ratio of the II-III(In)-VI(S) compound thin film of the n-type layer 104 is important to obtain a photoelectric conversion characteristic. A target composition ratio is set to a composition ratio of vapor deposition sources in the case of the vacuum vapor deposition method, and to a composition ratio of a sputtering target in the case of the sputtering method, film formation conditions are adjusted, and then finally the target composition ratio is decided in the state of the II-III(In)-VI(S) compound thin film. As the composition ratio changes, characteristics of carrier concentration and mobility are changed. For example, the stoichiometric composition of Zn—In—S is Zn:In:S=1:2:4, but it is preferable for a solar battery characteristic to have composition deviated from the aforementioned composition. Crystal having the stoichiometric composition is classified into a defect chalcopyrite system, and thus is a material system differently classified from a chalcopyrite system such as CuInSe₂ or CuInS₂. As a manufacturing method, a composition ratio of a vapor deposition source or a sputtering target (starting material) is about Zn:In:S=1:2:4 in terms of an atomic ratio, in other words, if In is set as a balancing element, a S-to-Zn ratio is set to 0.25, and using the starting materials of the S-to-Zn ratio of about 0.25, the S-to-Zn ratio is set so as to fall within the range of 0.2 to 0.3 according to a film formation condition.

Since ZnInS is a ternary compound, there may be cases where it turns into states of mixtures of binary compounds depending on a preparation method and a preparation condition. For example, there may be a case where phase separation of binary compounds of In₂S₃ and ZnS occurs depending on a preparation method and a preparation condition. If there is such phase separation of binary compounds, a resistance value deviates from a range appropriate for a material of the photoelectric conversion layer. Thus, in order to suppress the phase separation of the binary compounds and have a resistance value appropriate for the material of the photoelectric conversion layer, a composition ratio of a ZnInS thin film is preferably in the range of 0.2 to 0.3 described above in terms of the S-to-Zn ratio. The range of 0.2 to 0.3 is preferable for another Group II—In—S thin film. Likewise for the II-III(In)-VI(S) compound thin film other than Zn—In—S, carrier concentration, mobility, a photocurrent (photocon) characteristic, Eg, and the like change according to a composition ratio of the film, and thus it is necessary to optimize the composition for each film formation method in order to obtain a desired solar battery characteristic.

A crystalline state of the II-III(In)-VI(S) compound thin film that is the n-type layer is preferably an amorphous or microcrystalline state. Here, the amorphous state refers to a state in which a half-value width of a diffraction peak in X-ray diffraction measurement is greater than 3°, and a half-value width of a diffraction peak has the value above even when a thin film that is an aggregate of extremely small crystal grains is measured using X-ray diffraction. Thus, it does not matter if a crystalline state of a compound thin film is an aggregate of extremely small crystal grains. For example, in the ZnInS thin film, phase separation of In₂S₃ and ZnS may occur depending on a manufacturing method. Presence or absence and the degree of such phase separation can he ascertained through X-ray diffraction measurement. Being in an amorphous state or the half-value width of the diffraction peak greater than 3° also indicates a state in which no remarkable phase separation of In₂S₃ and ZnS occurs.

—Second Electrode—

For the second electrode 105 positioned on a sunlight incident side, a transparent conductive film of ITO (In₂O₃—SnO₂), stannic oxide (SnO₂), ZnO:Al obtained by adding aluminum (Al) to zinc oxide (ZnO), or the like can be used. As a film formation method of the second electrode, the vacuum vapor deposition method, the sputtering method, or the like can be used. A thickness of the second electrode 105 is preferably 50 to 200 nm.

The first electrode 102, the p-type layer 103, the n-type layer 104, and the second electrode 105 shown in FIG. 1 are all formed using the sputtering method. As a sputtering target, a compound (alloy) target that is a compound state of constituent elements is used, but a target compound may be prepared through simultaneous film formation (co-sputtering) using a plurality of metal targets of the constituent elements. Note that, in FIG. 1, the example of the photoelectric conversion layer constituted with two layers of the p-type layer and the n-type layer has been shown, but a three-layer structure such as a p-i-n structure used in an amorphous Si solar battery or a structure constituted by a plurality of layers including an extraction layer for efficiently performing extraction carriers can be adopted.

—Other Members—

There is no particular limitation on other members, and thus a member can be appropriately selected according to purposes, and examples thereof include a gas barrier layer, a protective layer, a buffer layer, and the like. Examples of a material of the gas barrier layer include organic substances such as silicon nitride and silicon oxide.

The thin-film solar battery in this embodiment of the present invention enables generation of earners in the n-type semiconductor layer and satisfactorily high productivity efficiency to be compatible in order to realize high energy efficiency, can be used in various kinds of thin-film solar batteries, for example, an amorphous silicon solar battery, a solar battery using a compound semiconductor film, an organic thin-film solar battery, a dye-sensitized solar battery, and the like, and particularly, can be preferably used in the solar battery using a compound semiconductor film.

### EXAMPLES

Hereinafter, embodiments of the present invention will be more specifically described by way of Examples and Comparative Examples, but the present invention is not limited to Examples. Note that a composition ratio of a sputtering target is based on an atom ratio.

### Example 1

Using a glass substrate as the supporting substrate 101, each of layers was prepared using CuInGaSe as the p-type layer 103, ZnInS that is a Group 2 (Zn)-Group 13 (In)-Group 16 (S) compound thin film as the n-type layer 104, molybdenum (Mo) as the first electrode 102, and ZnO:Al as the second electrode 105, and thereby a thin-film solar battery of Example 1 having the structures of FIGS. 1 and 2 was prepared. Detailed manufacturing methods of each of the layers are as follows. Alkali-free glass having a thickness of 0.5 mm and a size of 30×30 mm was used for the glass substrate 101. A film of Mo of the first electrode 102 was formed using a direct current (DC) magnetron sputtering method with an input power of 3 kW in an argon (Ar) gas atmosphere. Since masking was not particularly performed for the area of the electrode, the film was formed substantially over the entire surface of the glass substrate. A film thickness thereof was 200 nm. A film of CuInGaSe of the p-type layer 103 was formed using a radio frequency (RF) magnetron sputtering method with an input power of 70 W in an argon (Ar) gas atmosphere. A composition ratio of a sputtering target was set to Cu:In:Ga:Se=25:17.5:7.5:50. The film formation area was set to the range of about 20×20 mm using metal masking. A film thickness thereof was 500 nm. A film of ZnInS of the n-type layer 104 was formed using the RF magnetron sputtering method with an input power of 70 W in an argon (Ar) gas atmosphere at a pressure of 0.6 Pa. A film formation temperature was set to room temperature, and then the film was formed in a state in which the substrate was not forcedly heated. A composition ratio of a sputtering target was set to Zn:In:S=1:2:4. A film formation area thereof was made to be the same as that of the p-type layer. A film thickness thereof was 500 nm. Post annealing was performed after the film formation of ZnInS. The post annealing was performed in a nitrogen atmosphere using an infrared heating furnace. An annealing temperature was set to 300° C. and pressure was set to the atmospheric pressure. After the annealing, a film of ZnO:Al of the second electrode 105 was formed using the DC magnetron sputtering method with an input power of 1 kW in an argon (Ar) gas atmosphere. A sputtering target obtained by adding 3% of Al to ZnO of Zn:O=1:1 was used. A film formation temperature was set to room temperature (the state in which the substrate was not forcedly heated). A film formation area thereof was made to be in a lattice state as shown in FIG. 2 using metal masking. A size of a lattice was set to about 2×2 mm. A film thickness thereof was 150 nm.

### Comparative Example 1

A thin-film solar battery of Comparative Example 1 was prepared in the same manner as in Example 1 except that AgInTe was used as the p-type layer 103. A film of AgInTe of the p-type layer 103 was formed using the RF magnetron sputtering method with an input power of 70 W in an argon (Ar) gas atmosphere. A composition ratio of a sputtering target was set to Ag:In:Te=1:1:2. A film thickness thereof was 500 nm.

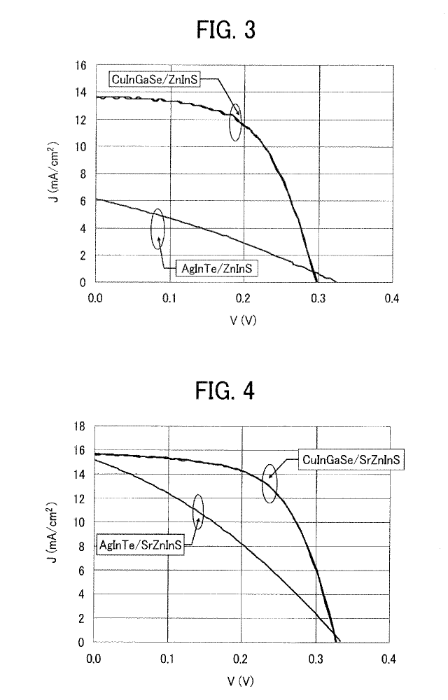

FIG. 3 shows current density-voltage (J-V) characteristics that are power generation characteristics of the thin-film solar batteries of Example 1 and Comparative Example 1. In evaluation of the J-V characteristics, a solar simulator using a pseudo sunlight source with an AM (air mass) of 1.5 and an intensity of 100 (mW/cm²) was used. Measurement was performed in the state in which bias voltage in the range of −0.1 V to +0.5 V was applied onto the Mo electrode side of the first electrode 102 and the ZnO:Al electrode side of the second electrode 105 was grounded. FIG. 3 shows an unbiased (0 V) state, so-called short-circuit current density (current density is a value obtained by dividing a measured current value by the area of the second electrode) Jsc, and a state in which a so-called open voltage Voc in which a current is zero becomes clear. In addition, a conversion efficiency of the thin-film solar battery of Example 1 was 2.3% and that of the thin-film solar battery of Comparative Example 1 was 0.6%. Based on the result, it can clearly be seen that the embodiments of the present invention obtains an excellent power generation characteristic. In other words, according to the embodiments of the present invention, it can be seen that a thin-film solar battery that enables energy efficiency and satisfactorily high production efficiency to be compatible, which was not realized in the related art, is obtained.

Next, the crystallinity of the ZnInS film was evaluated using X-ray diffraction at a post annealing temperature of 300° C. A ZnInS thin film was formed on the glass substrate using the same manner as in Example 1 so as to have a film thickness of 500 nm, then annealing was performed using the same manner as in Example 1, and measurement was performed. As a result of X-ray diffraction measurement performed with a voltage of 45 kV and a current of 40 mA using Cu-Kα rays, a clear diffraction peak was not found in an obtained diffraction profile, and the film was seen to be in an amorphous state.

### Comparative Example 2

A thin-film solar battery of Comparative Example 2 was prepared in the same manner as in Example 1 except that a temperature of post annealing after the film formation of ZnInS was changed to 500° C. As a result of setting power generation characteristics in the same manner as in Example 1, power generation was not attained. Next, the crystallinity of a ZnInS film at the post annealing temperature of 500° C. was evaluated using X-ray diffraction. The ZnInS thin film was formed on a glass substrate in the same manner as in Example 1 so as to have a film thickness of 500 nm, annealing was performed in the same manner as in Example 1, and then measurement was performed. As a result of X-ray diffraction measurement performed with a voltage of 45 kV and a current of 40 mA using Cu-Kα rays, a strong diffraction peak was observed at around 22° in an obtained diffraction profile. The ZnInS thin film annealed at 500° C. was seen to have greater crystal grains than the film annealed at 300° C., and was therefore an aligned film aligned in a certain crystal orientation.

### Example 2 and Comparative Example 3

Thin-film solar batteries of Example 2 and Comparative Example 3 were prepared in the same manner as in Example 1 and Comparative Example 1 except that ZnSrInS was used for the n-type layer 104. A film of ZnSrInS of the n-type layer 104 was formed through the co-sputtering method of ZnInS and SrS using the RF magnetron sputtering method. Composition ratios of the sputtering targets were set to Zn:In:S=1:2:4 and Sr:S=1:1, respectively. Film formation was performed in an argon (Ar) gas atmosphere at a pressure of 0.6 Pa. Sputtering powers were set to 70 W for ZnInS and 20 W for SrS. Film formation was performed at a film formation temperature set to room temperature in a state in which substrates were not forcedly heated. A film thickness was 500 nm. FIG. 4 shows current density-voltage (J-V) characteristics that are power generation characteristics of the thin-film solar batteries of Example 2 and Comparative Example 2. An evaluation method and a drawing notation method are the same as in Example 1 and Comparative Example 1. In addition, a conversion efficiency of the thin-film solar battery of Example 2 was 3.0% and that of the thin-film solar battery of Comparative Example 3 was 1.7%. Based on the result, it can be clearly seen that the embodiments of the present invention obtains an excellent power generation characteristic. In other words, according to the embodiments of the present invention, it can be seen that a thin-film solar battery that enables energy efficiency and satisfactorily high production efficiency to be compatible, which was not realized in the related art, is obtained.

### Examples 3 to 5 and Comparative Examples 4 and 5

Thin-film solar batteries were prepared in the same manner as in Example 1 after preparing CuInGaSe targets of which a Se amount was changed as shown in Table 1 with reference to the composition ratio of the sputtering target of CuInGaSe used in Example 1. Conversion efficiencies of each of the batteries are shown in Table 1. An evaluation method is the same as in Example 1. Data of Example 1 is also shown for the sake of comparison. The unit of the composition ratio is atomic %.

TABLE 1

| | | | | | Conversion |
|---|---|---|---|---|---|
| | Cu | In | Ga | Se | Efficiency |
| Example 1 | 25 | 17.5 | 7.5 | 50 | 2.3 |
| Example 3 | 27.5 | 19.2 | 8.3 | 45 | 1.8 |
| Example 4 | 22.5 | 15.8 | 6.7 | 55 | 2.5 |
| Example 5 | 20 | 14 | 6 | 60 | 2.6 |
| Comparative | 28.5 | 20 | 8.5 | 43 | 0.4 |
| Example 4 | | | | | |
| Comparative | 30 | 21 | 9 | 40 | 0.2 |
| Example 5 | | | | | |

Next, scanning electron microscope (SEM) observation was performed with respect to cross-sections of the produced thin film solar batteries, and the film compositions of CuInGaSe layers were measured using an energy dispersive X-ray spectroscopic (EDS) method. The results are shown in Table 2, and the unit of the composition ratio is atomic %.

TABLE 2

| | | | | | Conversion |
|---|---|---|---|---|---|
| | Cu | In | Ga | Se | Efficiency |
| Example 1 | 25 | 21 | 9 | 45 | 2.3 |
| Example 3 | 27.5 | 23 | 9 | 40.5 | 1.8 |
| Example 4 | 22.5 | 20 | 8 | 49.5 | 2.5 |
| Example 5 | 22 | 19.8 | 8.5 | 49.7 | 2.6 |
| Comparative | 28 | 23 | 10 | 39 | 0.4 |
| Example 4 | | | | | |
| Comparative | 29 | 25 | 10 | 36 | 0.2 |
| Example 5 | | | | | |

As understood from the results, the batteries of Examples clearly have an excellent power generation characteristic. In other words, according to the embodiments of the present invention, it can be seen that a thin-film solar battery that enables energy efficiency and satisfactorily high production efficiency to be compatible, which was not realized in the related art, is obtained.

### Example 6

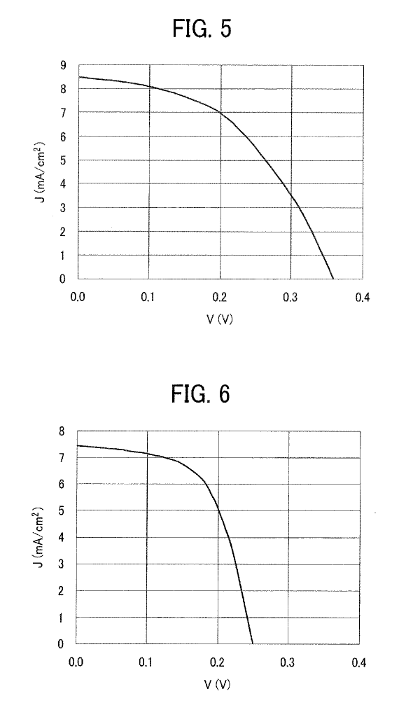

A thin-film solar battery of Example 6 was prepared in the same manner as in Example 1 except that ZnInOS was used for the n-type layer 104. A film of ZnInOS of the n-type layer 104 was formed through oxygen-reactive sputtering using the RF magnetron sputtering method. A composition ratio of a sputtering target was set to Zn:In:S=1:2:4. A film formation atmosphere was set to an argon (Ar) gas and oxygen (O₂) gas atmosphere, the pressure was set to 0.6 Pa, and an oxygen flow rate was set to 2.5% of an overall gas flow rate. Film formation was performed at a film formation temperature set to room temperature in a state in which substrates were not forcedly heated. A film thickness of the ZnInOS thin film was 500 nm. FIG. 5 shows a current density-voltage (J-V) characteristic that is a power generation characteristic of the thin-film solar battery of Example 6. An evaluation method and a drawing notation method are the same as in Example 1. A conversion efficiency of the thin-film solar battery of Example 6 was 1.4%.

### Example 7

A thin-film solar battery of Example 7 was prepared in the same manner as m Example 1 except that ZnInGaS was used for the n-type layer 104. A film of ZnInGaS that is the n-type layer 104 was formed through the co-sputtering method of ZnInS and ZnGaS using the RF magnetron sputtering method. Composition ratios of sputtering targets were set to Zn:In:S=1:2:4 and Zn:Ga:S=1:2:4, respectively. Film formation was performed in a film formation atmosphere set to an argon (Ar) gas atmosphere, at a pressure of 0.6 Pa, with sputtering powers of 70 W for ZnInS and 30 W for ZnGaS, and at a film formation temperature set to room temperature in the state in which the substrate was not forcedly heated. A film thickness of ZnInGaS was 500 nm. FIG. 6 shows a current density-voltage (J-V) characteristic that is a power generation characteristic of the thin-film solar battery of Example 7. An evaluation method and a drawing notation method are the same as in Example 1. A conversion efficiency of the thin-film solar battery of Example 7 was 1.1%.

### Example 8

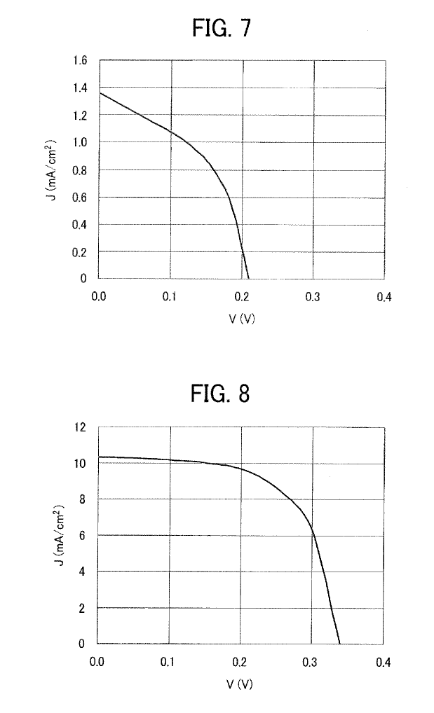

A thin-film solar battery of Example 8 was prepared in the same manner as in Example 1 except that ZnMnInS was used for the n-type layer 104. A film of ZnMnInS that is the n-type layer 104 was formed through the co-sputtering method of ZnInS and MnInS using the RF magnetron sputtering method. Composition ratios of sputtering targets were set to Zn:In:S=1:2:4 and Mn:In:S=1:2:4, respectively. Film formation was performed in a film formation atmosphere set to an argon (Ar) gas atmosphere, at a pressure of 0.6 Pa, with sputtering powers of 70 W for ZnInS and 30 W for MnInS, and at a film formation temperature set to room temperature in the state in which the substrate was not forcedly heated. A film thickness of ZnMnInS was 500 nm. FIG. 7 shows a current density-voltage (J-V) characteristic that is a power generation characteristic of the thin-film solar battery of Example 8. An evaluation method and a drawing notation method are the same as in Example 1. A conversion efficiency of the thin-film solar battery of Example 8 was 0.13%.

### Example 9

A thin-film solar battery of Example 9 was prepared in the same manner as in Example 1 except that ZnSrInGaS was used for the n-type layer 104. A film of ZnSrInGaS that is the n-type layer 104 was formed through the co-sputtering method of ZnGaS and SrInS using the RF magnetron sputtering method. Composition ratios of sputtering targets were set to Zn:Ga:S=1:2:4 and Sr:In:S=1:2:4, respectively. Film formation was performed in a film formation atmosphere set to an argon (Ar) gas atmosphere, at a pressure of 0.6 Pa, with sputtering powers of 40 W for ZnGaS and 70 W for SrInS, and at a film formation temperature set to room temperature in the state in which the substrate was not forcedly heated. A film thickness of ZnSrInGaS was 500 nm. FIG. 8 shows a current density-voltage (J-V) characteristic that is a power generation characteristic of the thin-film solar battery of Example 9. An evaluation method and a drawing notation method are the same as in Example 1. A conversion efficiency of the thin-film solar battery of Example 9 was 2.2%.

### Example 10

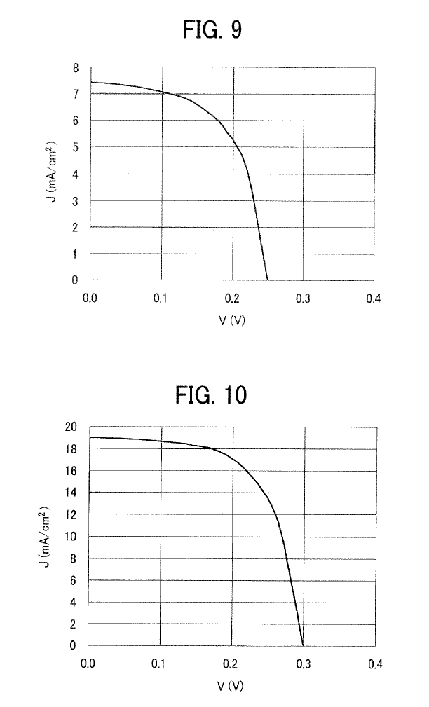

A thin-film solar battery of Example 10 was prepared in the same manner as in Example 1 except that CaInS was used for the n-type layer 104. A film of CaInS that is the n-type layer 104 was formed using the RF magnetron sputtering method. A composition ratio of a sputtering target was set to Ca:In:S=1:2:4. Film formation was performed in a film formation atmosphere set to an argon (Ar) gas atmosphere, at a pressure of 0.6 Pa, a sputtering power of 70 W, and at a film formation temperature set to room temperature in the state in which the substrate was not forcedly heated. A film thickness of CaInS was 500 nm. FIG. 9 shows a current density-voltage (J-V) characteristic that is a power generation characteristic of the thin-film solar battery of Example 10. An evaluation method and a drawing notation method are the same as in Example 1. A conversion efficiency of the thin-film solar battery of Example 10 was 1.1%.

### Example 11

A thin-film solar battery of Example 11 was prepared in the same manner as in Example 1 except that ZnInSSe was used for the n-type layer 104. A thin film of ZnInSSe that is the n-type layer 104 was formed through the co-sputtering method of ZnInS and Se using the RF magnetron sputtering method. Composition ratios of sputtering targets were set to ZnIn:S=1:2:4 and Se=1, respectively, and sputtering powers were set to 70 W for ZnInS and 30 W for Se. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the ZnInSSe thin film was 500 nm. FIG. 10 shows a current density-voltage (J-V) characteristic that is a power generation characteristic of the thin-film solar battery of Example 11. An evaluation method and a drawing notation method are the same as in Example 1. A conversion efficiency of the thin-film solar battery of Example 11 was 3.5%.

### Example 12

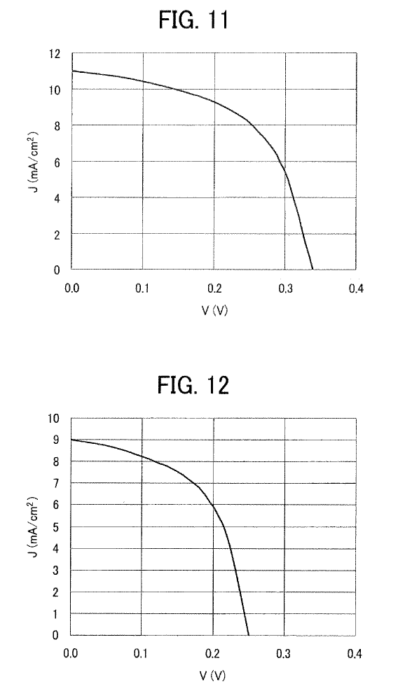

A thin-film solar battery of Example 12 was prepared in the same manner as in Example 1 except that ZnMgInS was used for the n-type layer 104. A thin film of ZnMgInS that is the n-type layer 104 was formed through the co-sputtering method of ZnInS and MgS using the RF magnetron sputtering method. Composition ratios of sputtering targets were set to Zn:In:S=1:2:4 and Mg:S=1:1, respectively, and sputtering powers were set to 70 W for ZnInS and 20 W for MgS. Film formation was performed in a film formation atmosphere set to an argon (Ar) gas atmosphere, at a pressure of 0.6 Pa, and at a film formation temperature set to room temperature m the state in which the substrate was not forcedly heated. A thickness of the ZnMgInS thin film was 500 nm. FIG. 11 shows a current density-voltage (J-V) characteristic that is a power generation characteristic of the thin-film solar battery of Example 12. An evaluation method and a drawing notation method are the same as in Example 1. A conversion efficiency of the thin-film solar battery of Example 12 was 2.0%.

### Example 13

A thin-film solar battery of Example 13 was prepared in the same manner as in Example 1 except that CaSrInS was used for the n-type layer 104. A thin film of CaSrInS that is the n-type layer 104 was formed through the co-sputtering method of CaInS and SrInS using the RF magnetron sputtering method. Composition ratios of sputtering targets were set to Ca:In:S=1:2:4 and Sr:In:S=1:2:4, respectively, and sputtering powers were set to 40 W for both CaInS and SrInS. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the CaSrInS thin film was 500 nm. FIG. 12 shows a current density-voltage (J-V) characteristic that is a power generation characteristic of the thin-film solar battery of Example 13. An evaluation method and a drawing notation method are the same as in Example 1. A conversion efficiency of the thin-film solar battery of Example 13 was 1.2%.

### Example 14

A thin-film solar battery of Example 14 was prepared in the same manner as in Example 1 except that SrBaInS was used for the n-type layer 104. A thin film of SrBaInS that is the n-type layer 104 was formed through the co-sputtering method of BaInS and SrInS using the RF magnetron sputtering method. Composition ratios of sputtering targets were set to Ba:In:S=1:2:4 and Sr:In:S=1:2:4, respectively, and sputtering powers were set to 30 W for BaInS and 50 W for SrInS. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the SrBaInS thin film was 500 nm. FIG. 13 shows a current density-voltage (J-V) characteristic that is a power generation characteristic of the thin-film solar battery of Example 14. An evaluation method and a drawing notation method are the same as in Example 1. A conversion efficiency of the thin-film solar battery of Example 14 was 1.3%.

### Example 15

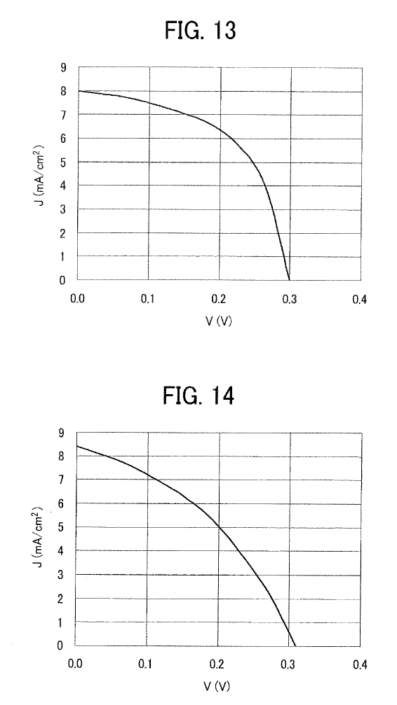

A thin-film solar battery of Example 15 was prepared in the same manner as in Example 1 except that ZnInSTe was used for the n-type layer 104. A thin film of ZnInSTe that is the n-type layer 104 was formed through the co-sputtering method of ZnInS and ZnTe using the RF magnetron sputtering method. Composition ratios of sputtering targets were set to Zn:In:S=1:2:4 and Zn:Te=1:1, respectively, and sputtering powers were set to 70 W for ZnInS and 20 W for ZnTe. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the ZnInSTe thin film was 500 nm. FIG. 14 shows a current density-voltage (J-V) characteristic that is a power generation characteristic of the thin-film solar battery of Example 15. An evaluation method and a drawing notation method are the same as in Example 1. A conversion efficiency of the thin-film solar battery of Example 15 was 1.0%.

### Example 16

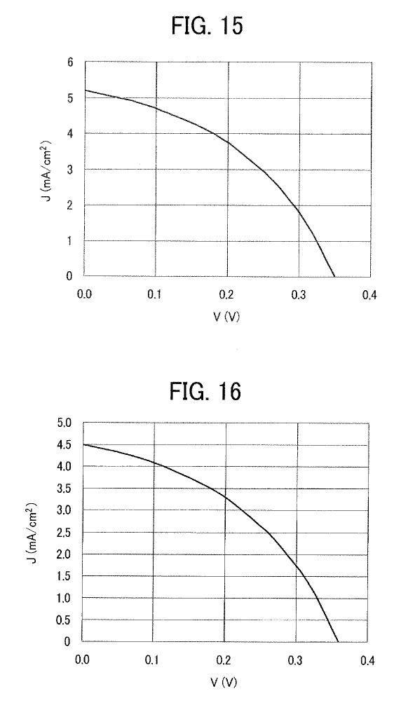

A thin-film solar battery of Example 16 was prepared in the same manner as in Example 1 except that ZnAlInSO was used for the n-type layer 104. A thin film of ZnAlInSO that is the n-type layer 104 was formed through the co-sputtering method of ZnInS and AlO using the RE magnetron sputtering method. Composition ratios of sputtering targets were set to Zn:In:S=1:2:4 and Al:O=2:3, respectively, and sputtering powers were set to 70 W for ZnInS and 50 W for AlO. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the ZnAlInSO thin film was 500 nm. FIG. 15 shows a current density-voltage (J-V) characteristic that is a power generation characteristic of the thin-film solar battery of Example 16. An evaluation method and a drawing notation method are the same as in Example 1. A conversion efficiency of the thin-film solar battery of Example 16 was 0.76%.

### Example 17

A thin-film solar battery of Example 17 was prepared in the same manner as in Example 1 except that ZnBInSO was used for the n-type layer 104. A thin film of ZnBInSO that is the n-type layer 104 was formed through the co-sputtering method of ZnInS and BO using the RF magnetron sputtering method. Composition ratios of sputtering targets were set to Zn:In:S=1:2:4 and B:O=2:3, respectively, and sputtering powers were set to 70 W for ZnInS and 60 W for BO. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the ZnBInSO thin film was 500 nm. FIG. 16 shows a current density-voltage (J-V) characteristic that is a power generation characteristic of the thin-film solar battery of Example 17. An evaluation method and a drawing notation method are the same as in Example 1. A conversion efficiency of the thin-film solar battery of Example 17 was 0.67%.

### Comparative Examples 6 to 9

Thin-film solar batteries of Comparative Examples 6 to 9 were prepared in the same manner as in Example 1 except that ZnO in Comparative Example 6, ZnS in Comparative Example 7, CaS in Comparative Example 8, and SrS in Comparative Example 9 were used for the n-type layer 104. The thin films that are the n-type layers 104 of Comparative Examples 6 to 9 were formed using the RF magnetron sputtering method. The compositions of sputtering targets and sputtering powers thereof are respectively shown in Table 3. Film formation was performed in a film formation atmosphere set to an argon (Ar) gas atmosphere, at a pressure of 0.6 Pa, and at a film formation temperature set to room temperature in the state in which the substrates were not forcedly heated. Thicknesses of all of the films were 500 nm.

TABLE 3

| | Composition of | Sputtering |
|---|---|---|
| | Sputtering Target | Power (W) |
| Comparative | Zn:O = 1:1 | 100 |
| Example 6 | | |
| Comparative | Zn:S = 1:1 | 70 |
| Example 7 | | |
| Comparative | Ca:S = 1:1 | 120 |
| Example 8 | | |
| Comparative | Sr:S = 1:1 | 120 |
| Example 9 | | |

The power generation characteristics of the thin-film solar batteries of Comparative Examples 6 to 9 were evaluated in the same manner as in Example 1, but no power generation characteristic was obtained in any case.

### Comparative Examples 10 to 13

Thin-film solar batteries of Comparative Examples 10 to 13 were prepared in the same manner as in Example 1 except that ZnCaS in Comparative Example 10, ZnCaSO in Comparative Example 11, ZnSrS in Comparative Example 12, and ZnSrSO in Comparative Example 13 were used for the n-type layer 104. The thin films that are the n-type layers 104 of Comparative Examples 10 to 13 were formed using the RF magnetron sputtering method. The compositions of sputtering targets and sputtering powers thereof are respectively shown in Table 4. Film formation was performed in a film formation atmosphere set to an argon (Ar) gas atmosphere, at a pressure of 0.6 Pa, and at a film formation temperature set to room temperature in the state in which the substrates were not forcedly heated. Thicknesses of all of the films were 500 nm.

TABLE 4

| | Composition of | Sputtering |
|---|---|---|
| | Sputtering Target | Power (W) |
| Comparative | Zn:S = 1:1 | 70 |
| Example 10 | Ca:S = 1:1 | 120 |
| Coraparative | Zn:O = 1:1 | 100 |
| Example 11 | Ca:S = 1:1 | 120 |
| Comparative | Zn:S = 1:1 | 70 |
| Example 12 | Sr:S = 1:1 | 120 |
| Comparative | Zn:O = 1:1 | 100 |
| Example 13 | Sr:S = 1:1 | 120 |

The power generation characteristics of the thin-film solar batteries of Comparative Examples 10 to 13 were evaluated in the same manner as in Example 1, but no power generation characteristic was obtained in any case.

### Comparative Example 14

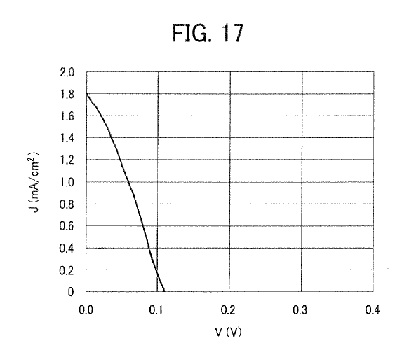

A thin-film solar battery of Comparative Example 14 was prepared in the same manner as in Example 1 except that InS was used for the n-type layer 104. A thin film of InS that is the n-type layer 104 was formed using the RF magnetron sputtering method. A composition ratio of a sputtering target was set to In:S=2:3, and a sputtering power was set to 70 W. Film formation was performed in a film formation atmosphere set to an argon (Ar) gas atmosphere, at a pressure of 0.6 Pa, and at a film formation temperature set to room temperature in the state in which the substrate was not forcedly heated. A thickness of the InS thin film was 500 nm. FIG. 17 shows a current density-voltage (J-V) characteristic that is a power generation characteristic of the thin-film solar battery of Comparative Example 14. An evaluation method and a drawing notation method are the same as in Example 1. A conversion efficiency of the thin-film solar battery of Comparative Example 14 was 0.06%.

### Example 18

A thin-film solar battery of Example 18 was prepared in the same manner as in Example 1 except that the CuInGaSe layer, which was the p-type layer 103 used in Example 1, was formed at a different film thickness from that in Example 1.

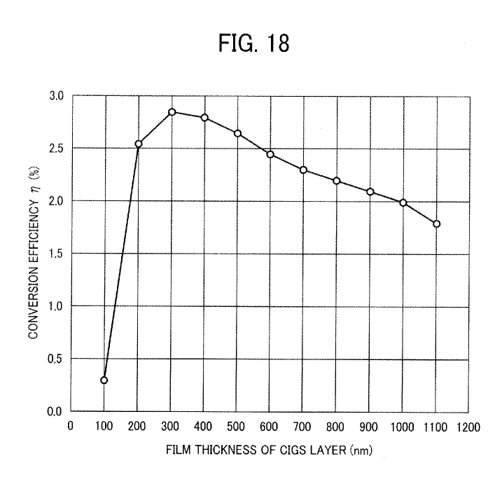

FIG. 18 shows a dependence of the conversion efficiency that is a power generation characteristic of the thin-film solar battery of Example 18 on the film thickness of the CuInGaSe layer. An evaluation method and a drawing notation method are the same as in Example 1.

The thin-film solar battery of Example 18 had conversion efficiencies of 2.0% or greater in a range of film thickness from 200 nm to 1000 nm, and conversion efficiencies of 2.5% or greater in a range of film thickness from 200 nm to 500 nm.

### Example 19

A thin-film solar battery of Example 19 was prepared in the same manner as in Example 1 except that the CuInGaSe layer, which was the p-type layer 103 used in Example 11, was formed at a different film thickness from that in Example 11.

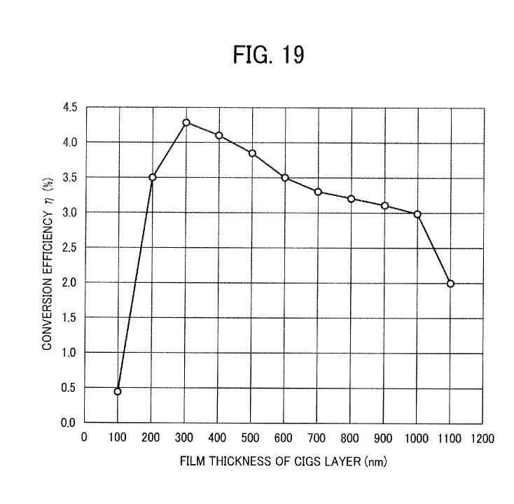

FIG. 19 shows a dependence of the conversion efficiency that is a power generation characteristic of the thin-film solar battery of Example 19 on the film thickness of the CuInGaSe layer. An evaluation method and a drawing notation method are the same as in Example 1.

The thin-film solar battery of Example 19 had conversion efficiencies of 3.0% or greater in a range of film thickness from 200 nm to 1000 nm, and conversion efficiencies of 3.5% or greater in a range of film thickness from 200 nm to 500 nm.

Numerous additional modifications and variations are possible in light of the above teachings. It is therefore to be understood that, within the scope of the above teachings, the present invention may be practiced otherwise than as specifically described herein. With some embodiments having thus been described, it will be obvious that the same may be varied in many ways. Such variations are not to be regarded as a departure from the scope of the present invention, and all such modifications are intended to be included within the scope of the present invention.

What is claimed is:

1. A thin-film solar battery comprising:
a substrate;
a first electrode;
a photoelectric conversion layer; and
a second electrode,
the first electrode, the photoelectric conversion layer, and the second electrode being laminated on the substrate,
wherein the photoelectric conversion layer has a laminated layer structure which includes at least a p-type layer and an n-type layer,
wherein the p-type layer is formed of Cu, In, Ga, and Se, and a composition ratio of Se of the p-type layer is equal to or higher than 40 atomic % and less than 50 atomic %, and
wherein the n-type layer is a compound of an element of at least one Group selected from Group 2, Group 7, and Group 12, an element of Group 13, and an element of Group 16, and contains at least In as the element of Group 13 and at least S as the element of Group 16.

2. The thin-film solar battery according to claim 1, wherein element of at least one Group selected from Group 2, Group 7, and Group 12 in the n-type layer is at least one selected from Mg, Ca, Sr, Ba, Zn, Cd, and Mn.

3. The thin-film solar battery according to claim 1, wherein the n-type layer contains at least one of Ga, Al, and B as the element of Group 13 in addition to In, and contains at least one of Te, Se, and O as the element of Group 16 in addition to S.

4. The thin-film solar battery according to claim 1, wherein the n-type layer contains Zn, In, and S or Zn, Sr, In, and S.

5. The thin-film solar battery according to claim 1, wherein a structural state of the n-type layer is an amorphous state.

6. The thin-film solar battery according to claim 1, wherein the photoelectric conversion layer is formed using a sputtering method, and the p-type layer is formed without using a process of selenization or of supplementing elemental selenium using Se or H₂Se.

7. A method of making the thin-film solar battery according to claim 1, the method comprising:
forming the photoelectric conversion layer using a sputtering method; and
forming the p-type layer without using a process of selenization or of supplementing elemental selenium using Se or H₂Se.
